(19) United States
(12) Patent Application Publication
(10) Pub. No.: US 2006/0228885 A1
(43) Pub. Date: Oct. 12, 2006

(54) Method of manufacturing semiconductor device

(76) Inventor: Tomohiro Saito, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/266,241

(22) Filed: Nov. 4, 2005

(30) Foreign Application Priority Data
Apr. 8, 2005 (JP) 2005-112173

(51) Int. Cl. H01L 21/44; H01L 21/28; H01L 21/4763

(52) U.S. Cl. 438/650; 438/580

(57) ABSTRACT

A method of manufacturing a semiconductor device includes forming a gate insulation film on a semiconductor substrate; forming a gate electrode on the gate insulation film; depositing a metal film on the gate electrode; siliciding an upper part of the gate electrode by carrying out a first heat treating; removing the metal film not silicided in the first heat treating; and siliciding the gate electrode to a lower part of the gate electrode by carrying out a second heat treating.

### CROSS-REFERENCE TO RELATED APPLICATION

This application is based upon and claims the benefit of priority from the prior Japanese Patent Applications No. 2005-112173, filed on Apr. 8, 2005, the entire contents of which are incorporated herein by reference.

### BACKGROUND OF THE INVENTION

1. Field of the Invention

The present invention relates to a method of manufacturing a semiconductor device.

2. Background Art

In recent years, manufacturing a MOSFET having the whole gate electrode silicided (hereinafter, “fully silicided”) on a semiconductor substrate is considered. This fully silicided electrode can be employed in a transistor of a logic circuit, a memory circuit, or an analog circuit.

MOSFETs formed on the same semiconductor substrate have differences in a gate length and a gate width of the gate electrodes. The proceeding of the siliciding process is different depending on different patterns of the gate electrodes. Therefore, it is hard to fully silicide the gates of all patterns.

For example, siliciding proceeds fast in the case of a pattern of a gate electrode having a small area of a gate pattern. This is because metal at a constant ratio to the material of a gate electrode is necessary, and much metal is supplied from the periphery of the gate electrode in the pattern of the gate electrode having a small area. Therefore, in this case, the gate electrode can be easily fully silicided, and can become silicide having a large content ratio of metal. The silicide having a large content ratio of metal has a risk that the silicide is etched together with metal in the etching process of removing surplus metal. Therefore, there is a problem in that the gate electrode itself is etched in the etching process.

On the other hand, siliciding proceeds slowly in the case of a pattern of a gate electrode having a large area of a gate pattern. This is because metal is not supplied sufficiently from the periphery of the gate electrode in the siliciding process. Therefore, in this case, there is a problem in that the gate electrode cannot be easily fully silicided (see U.S. Pat. No. 6,555,453 Specification).

To overcome the above difficulties, a method of manufacturing a semiconductor device capable of easily fully siliciding a gate electrode having various patterns is provided.

### SUMMARY OF THE INVENTION

A method of manufacturing a semiconductor device according to am embodiment of the present invention includes forming a gate insulation film on a semiconductor substrate; forming a gate electrode on the gate insulation film; depositing a metal film on the gate electrode; siliciding an upper part of the gate electrode by carrying out a first heat treating; removing the metal film not silicided in the first heat treating; and siliciding the gate electrode to a lower part of the gate electrode by carrying out a second heat treating.

A method of manufacturing a semiconductor device according to am embodiment of the present invention includes forming a gate insulation film on a semiconductor substrate; depositing a gate electrode material on the gate insulation film; depositing a cap material on -the gate electrode material to cover the gate electrode material; patterning the gate electrode material and the cap material in a gate electrode pattern to form a gate electrode and a cap; forming spacers on said side surfaces of the gate electrode and on said side surfaces of the cap; forming a source-drain layer on the semiconductor substrate using the gate electrode as a mask; depositing a first metal film on the source-drain layer; siliciding a surface of the source-drain layer with the first metal film; depositing an insulating material to cover the source-drain layer; planarizing the insulating material to expose the upper surface of the insulating material; removing the cap; depositing a second metal film on an upper surface of the gate electrode; siliciding an upper part of the gate electrode by carrying out a first heat treating; removing the second metal film not silicided in the first heat treating; and siliciding the gate electrode to a lower part of the gate electrode by carrying out a second heat treating.

### BRIEF DESCRIPTION OF THE DRAWINGS

FIG. 1 is a cross-sectional view showing a method of manufacturing a semiconductor device according to an embodiment of the present invention;

FIG. 2 is a cross-sectional view showing a method of manufacturing a semiconductor device following FIG. 1;

FIG. 3 is a cross-sectional view showing a method of manufacturing a semiconductor device following FIG. 2;

FIG. 4 is a cross-sectional view showing a method of manufacturing a semiconductor device following FIG. 3;

FIG. 5 is a cross-sectional view showing a method of manufacturing a semiconductor device following FIG. 4; and

FIGS. 6 to 12 show a modification of the above embodiment.

### DETAILED DESCRIPTION OF THE INVENTION

Hereafter, embodiments of the present invention will be described with reference to the drawings. Note that the invention is not limited by the embodiments.

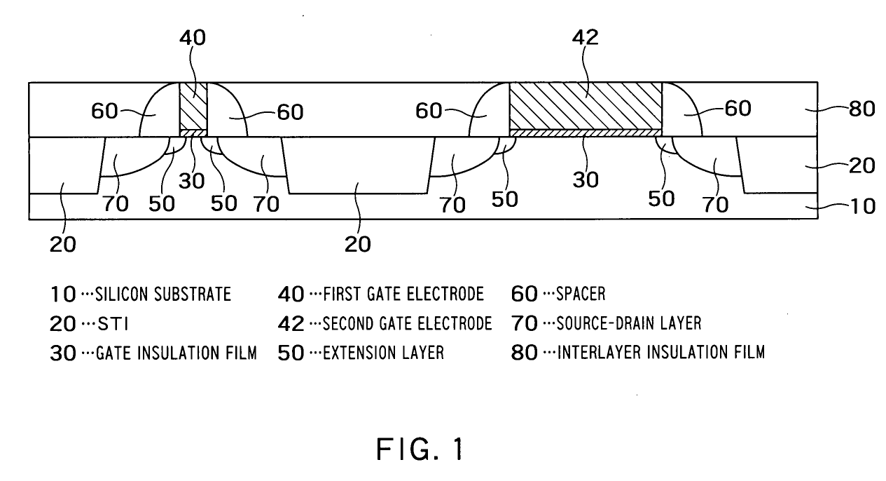

FIGS. 1 to 5 are cross-sectional views showing a flow of a method of manufacturing a semiconductor device according to an embodiment of the present invention. These diagrams show, for convenience sake, one MOSFET having a smaller surface area of a semiconductor substrate 10, and one MOSFET having a larger surface area of the semiconductor substrate 10. In actual practice, a large number of these MOSFETs are formed on a silicon substrate. Hereinafter, the area of the surface of the semiconductor 10 is also simply called an “area”.

As shown in FIG. 1, first, an element isolation area, that is, a shallow trench isolation (STI) 20, is formed on the silicon substrate 10. For example, at first, a silicon oxide film and a silicon nitride film (not shown) are deposited on the silicon substrate 10. Next, a silicon nitride film is patterned using a photolithography technique or an RIE method. The silicon oxide film and the silicon substrate 10 are etched to a predetermined depth by using the patterned silicon nitride film as a mask, thereby forming a trench. Next, a silicon oxide film is deposited on the whole surface of the silicon substrate 10, and a silicon oxide film is filled in the trench. The silicon oxide film is flattened by chemical mechanical polishing (CMP) or the like. The shallow trench isolation 20 is completed by removing the silicon nitride film.

Thereafter, a gate insulation film 30 is formed on the whole surface of the silicon substrate 10. For example, a thermally-oxidized film is formed on the surface of the silicon substrate 10 by thermally oxidizing the silicon substrate 10. The gate insulation film 30 can be an oxynitrided film or a nitrided film formed by further nitriding the thermally-oxidized film. Alternatively, the gate insulation film 30 can be a high dielectric film such as a hafnium oxide film or a hafnium silicate. A thickness of the gate insulation film 30 is 3 nm or below, for example.

Next, a first gate electrode 40 and a second gate electrode 42 made of polysilicon are formed on the gate insulation film 30. For example, polysilicon is deposited on the gate insulation film 30. A thickness of this polysilicon is 100 nm, for example. This polysilicon is formed in a gate pattern using the photolithography technique and anisotropic etching like the RIE. As a result, the first gate electrode 40 and the second gate electrode 42 are formed. The first gate electrode 40 has a gate length of 0.3 μm or less, for example, and the second gate electrode has a gate length of 0.3 μm or above, for example. For the material of the first gate electrode 40 and the second gate electrode 42, amorphous silicon can be used in place of polysilicon. For convenience sake, a depth (a gate width) of the first gate electrode 40 and that of the second gate electrode 42 are equal to each other. Therefore, the area of the second gate electrode 42 is larger than that of the first gate electrode 40.

Next, an ion implantation is carried out to form an extension (i.e., a lightly doped drain (LDD)) layer 50. Next, a spacer 60 is formed on side surfaces of the first gate electrode 40 and the second gate electrode 42, respectively, and an ion implantation is carried out to form a source-drain layer 70. Next, the silicon substrate 10 is annealed to recover from a damage suffered due to the ion implantation, and to activate impurity. Consequently, the extension layer 50 and the source-drain layer 70 are formed. Next, an interlayer insulation film 80 such as a silicon oxide film is deposited on the whole surface, and this interlayer insulation film 80 is flattened by CMP or the like. In this case, the interlayer insulation film 80 is polished until when the upper surfaces of the first gate electrode 40 and the second gate electrode 42 are exposed. As a result, a configuration as shown in FIG. 1 is obtained.

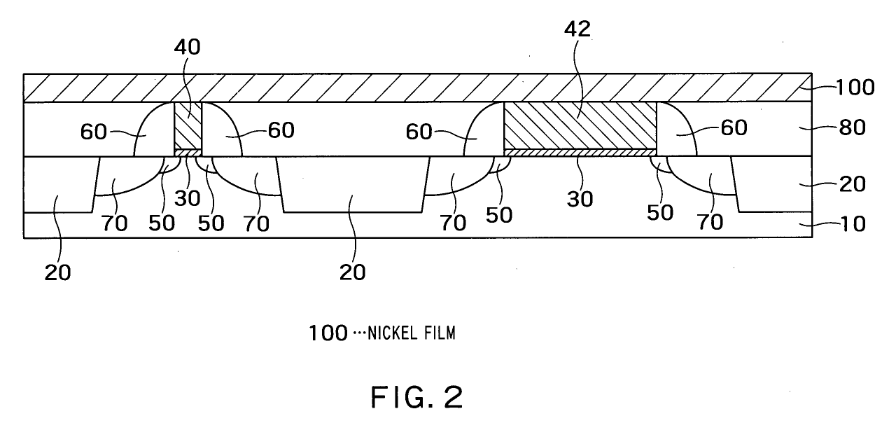

Next, as shown in FIG. 2, a nickel film 100 is deposited as a metal film for silicide. The nickel film 100 has a thickness of 70% or below of the thickness of the gate electrodes 40 and 42. For example, when the thickness of the gate electrodes 40 and 42 is 100 nm, the thickness of the nickel film 100 may be 60% of the thickness of the gate electrodes 40 and 42, that is, 60 nm.

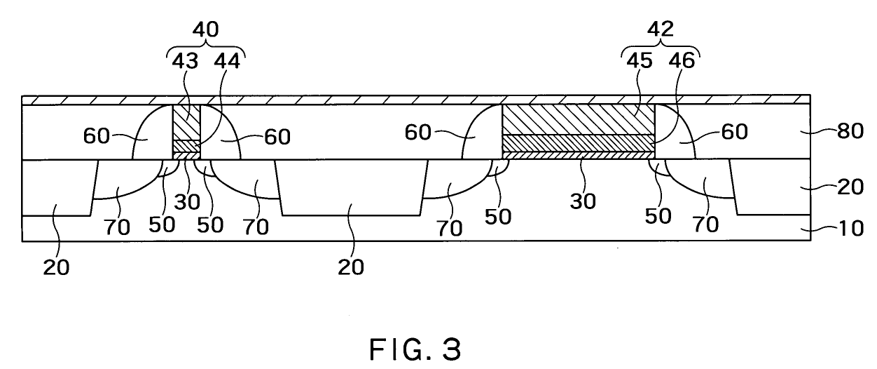

Next, the silicon substrate 10 is heat treated at a temperature within a range from 250° C. to 400° C. using rapid thermal annealing (RTA) for 20 or more seconds. Preferably, the silicon substrate 10 is heat treated at a temperature within a range from 300° C. to 400° C. for 20 or more seconds in order to accelerate the silicidation. More preferably, the silicon substrate 10 is heat treated at a temperature within a range from 325° C. to 375° C. for 30 or more seconds in order to assure to silicide the upper parts of the gate electrode 40, 42. Hereinafter, this is referred to a first heat treating. In the first heat treating, the first gate electrode 40 and the second gate electrode 42 are silicided with the nickel film 100, as shown in FIG. 3. The first heat treating is carried out at a relatively low temperature within a range from 250° C. to 400° C. (preferably, from 300° C. to 400° C. or from 325° C. to 375° C.). Therefore, only the upper parts of the first gate electrode 40 and the second gate electrode 42 are silicided, and polysilicon remains at the lower parts of these gate electrodes.

Based on the low-temperature RTA, composition of silicide layers 43 and 45 formed on the upper parts of the first gate electrode 40 and the second gate electrode 42, respectively, becomes NixSi (1<x<3). A portion near the upper surfaces of the silicide layers 43 and 45 near the nickel film 100 has composition of large nickel content (for example, NixSi (2<x<3). A portion near the bottom surfaces of the silicide layers 43 and 45 near the gate insulation film 30 has composition of small nickel content (for example, NiSi). The nickel content at a portion near the upper surfaces of the silicide layers 43 and 45 needs to be larger than the nickel content of NiSi, and also needs to be the content at which the portion is not etched by a remover of the nickel film (for example, a mixture of a hydrogen peroxide solution and sulfuric acid). Therefore, the temperature range in the first heat treating is limited to 250° C. to 400° C. This is because when the temperature in the first heat treating is lower than 250° C., the siliciding of the gate electrodes 40 and 42 progresses very slowly. On the other hand, when the temperature in the first heat treating exceeds 400° C., the composition of a portion near the upper surfaces of the silicide layers 43 and 45 becomes NixSi (x>3). In this case, the gate electrodes 40 and 42 are corroded by the remover of the nickel film (for example, a mixture of a hydrogen peroxide solution and sulfuric acid). When the heat treating time is less than 20 seconds, the siliciding of the gate electrodes 40 and 42 does not progress.

In order to suppress these inconveniences more effectively, it is preferable that the first heat treating is carried out at a temperature within a range from 325° C. to 375° C. for 30 or more seconds.

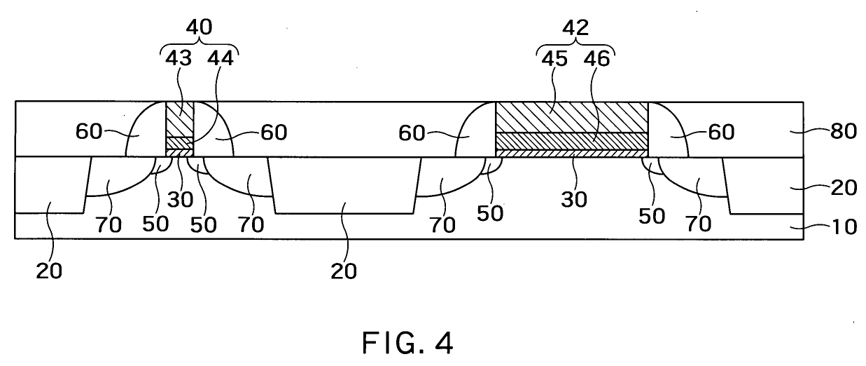

Next, as shown in FIG. 4, the nickel film 100 not silicided is etched using a mixture of a hydrogen peroxide solution and sulfuric acid. In this case, the electrodes 40 and 42 are not etched using this mixture.

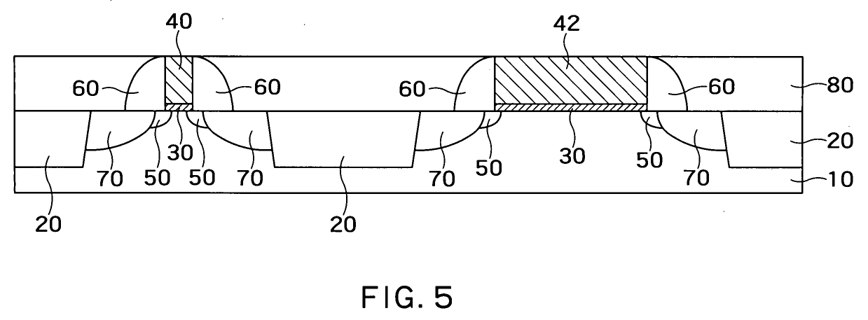

The silicon substrate 10 is heat treated at a temperature within a range from 450° C. to 550° C. using the RTA for 60 or more seconds. Typically, the silicon substrate 10 is heat treated at a temperature of 500° C. for 60 or more seconds. Hereinafter, this is referred a second heat treating. Based on this second heat treating, nickel contained by a large amount in the silicide layers 43 and 45 is diffused in the polysilicon layers 44 and 46 that remain at the lower parts of the gate electrodes 40 and. 42, respectively. Accordingly, the siliciding is progressed to the lower parts of the gate electrodes 40 and 42 that are in contact with the gate insulation film 30, thereby siliciding the polysilicon layers 44 and 46. As a result, as shown in FIG. 5, substantially the whole parts of the gate electrodes 40 and 42 are silicided.

The temperature in the second heat treating is limited to 450° C. to 550° C. This is because when the temperature in the second heat treating is lower than 450° C., the silicidation of the polysilicon layers 44 and 46 progresses very slowly. Also, when the temperature in the second heat treating exceeds 550° C., nickel is agglomerated.

In order to suppress these inconveniences more effectively, it is preferable that the second heat treating is carried out at a temperature of 500° C. for 60 or more seconds.

The subsequent steps of manufacturing can be the same as those of a normal transistor formation process. For example, after an oxide film (not shown) is deposited as an interlayer film, a contact and a wiring are formed. As a result, a semiconductor device is completed.

According to the present embodiment, the first gate electrode 40 and the second gate electrode 42 having various patterns can be fully silicided.

(Modification)

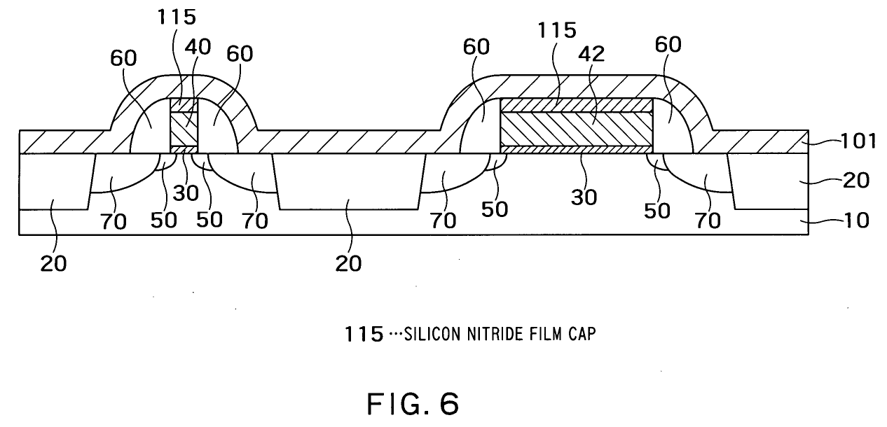

FIG. 6 to FIG. 12 show a modification of the above embodiment. This modification is different from the above embodiment in that a silicide layer 110 is formed on the source-drain layer 70. In the step of forming the silicide layer 110, a silicon nitride film cap 115 is provided on the first gate electrode 40 and the second gate electrode 42, respectively so as not to silicide the first gate electrode 40 and the second gate electrode 42. The first gate electrode 40, the second gate electrode 42, and the silicon nitride film cap 115 are formed as follows.

Through the same process as that according to the above embodiment, the gate insulation film 30 is formed on the silicon substrate 10. Next, polysilicon as a gate electrode material and a silicon nitride film as a cap material are deposited on the gate insulation film 30. The polysilicon and the silicon nitride film are formed in a gate electrode pattern using the photolithography technique and anisotropic etching like the RIE. As a result, the first gate electrode 40, the second gate electrode 42, and the silicon nitride film cap 115 are formed as shown in FIG. 6. The silicon nitride film cap 115 covers the upper surfaces of the first gate electrode 40 and the second gate electrode 42, respectively as a material for suppressing siliciding. A sidewall is formed according to needs, and then a nickel film 101 is deposited as a first metal film. As a result, a configuration as shown in FIG. 6 is obtained.

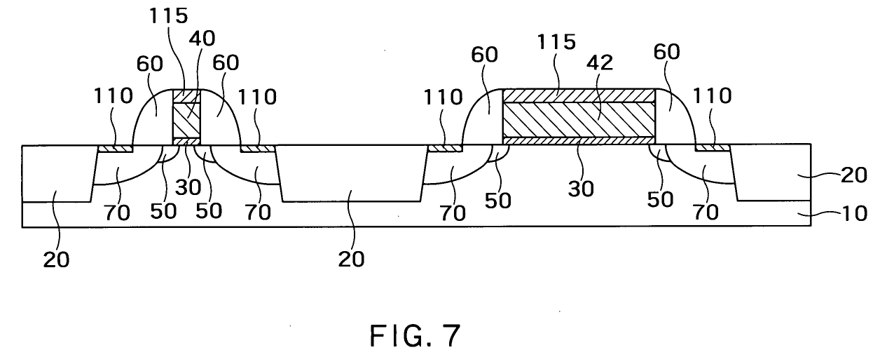

The silicon substrate 10 is heat treated, thereby forming the silicide layer 110 on the source-drain layer 70 as shown in FIG. 7. In this case, the silicon nitride film cap 115 prevents the first gate electrode 40 and the second gate electrode 42 from being silicided. Thereafter, the nickel film 101 is removed.

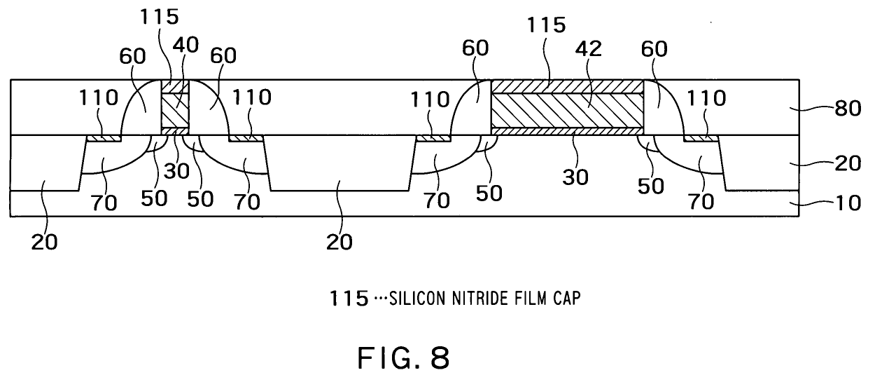

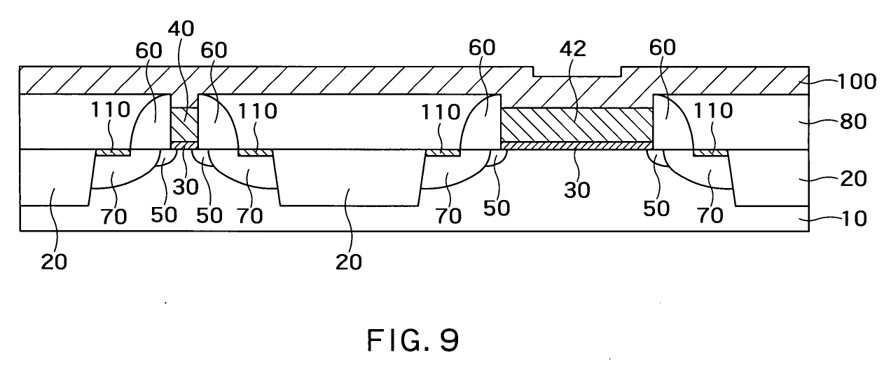

The interlayer insulation film 80 is deposited next. By polishing the interlayer insulation film 80 by CMP, the upper surface of the silicon nitride film cap 115 is exposed as shown in FIG. 8. The silicon nitride film cap 115 is removed next. As shown in FIG. 9, the nickel film 100 is deposited as a second metal film to silicide the gate electrodes 40 and 42. A thickness of the nickel film 100 is equal to or smaller than 70% of the thickness of the gate electrodes 40 and 42, like in the above embodiment.

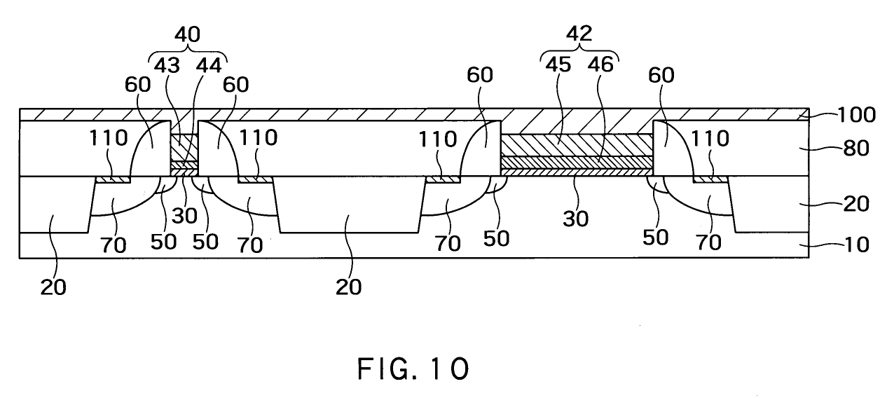

The first heat treating is executed next. Accordingly, as shown in FIG. 10, only the upper parts of the first gate electrode 40 and the second gate electrodes 42 are silicided, and polysilicon remains at their lower parts. A configuration and composition of the gate electrodes 40 and 42 shown in FIG. 10 can be the same as the configuration and the composition of the gate electrodes 40 and 42 as shown in FIG. 3.

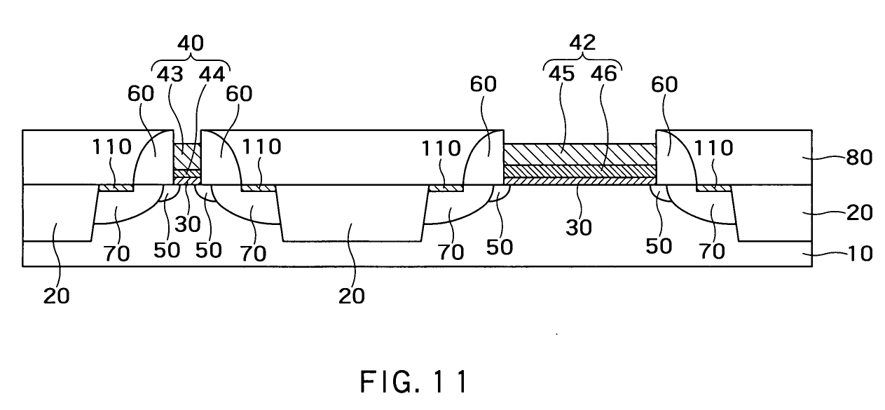

Next, as shown in FIG. 11, the nickel film 100 not silicided is etched using a mixture of a hydrogen peroxide solution and sulfuric acid. In this case, the electrodes 40 and 42 are not etched using this mixture.

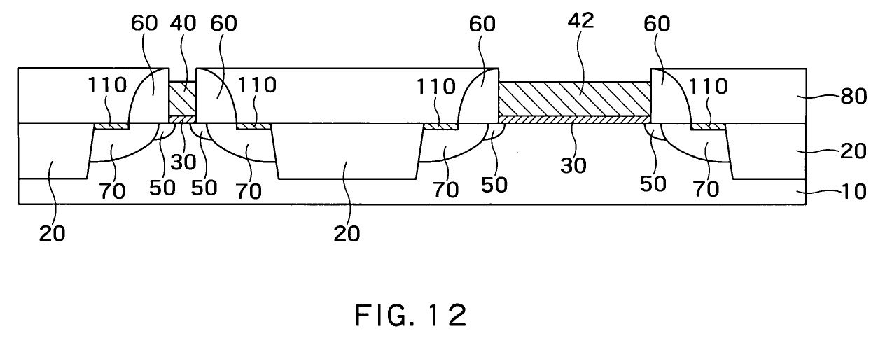

The second heat treating is carried out next. Based on this second heat treating, nickel contained by a large amount in the silicide layers 43 and 45 is diffused in the polysilicon layers 44 and 46 that remain at the lower parts of the gate electrodes 40 and 42, respectively. Accordingly, the siliciding is progressed to the lower parts of the gate electrodes 40 and 42 that are in contact with the gate insulation film 30, thereby siliciding the polysilicon layers 44 and 46. As a result, as shown in FIG. 12, substantially the whole parts of the gate electrodes 40 and 42 are silicided. Thereafter, a semiconductor device is completed through the same process as that according to the above embodiment.

In the above embodiment and the above modification, the first and the second heat treating can be carried out using a usual electric furnace, in place of the RTA. In this case, the heat treating time in the first and the second heat treating is longer than that using the RTA.

In order to control a threshold voltage of a transistor, impurity can be introduced in advance into the polysilicon that becomes a material of the first and the second gate electrodes 40 and 42, before the polysilicon is processed in a gate pattern.

The material of the first and the second gate electrodes 40 and 42 can be amorphous silicon.

The metal films 100 and 101 are not limited to nickel, and can be titanium (Ti), cobalt (Co), platinum (Pt), tungsten (W), erbium (Er), Yttrium (Y), niobium (Nb), or palladium (Pd), or the like. Furthermore, the metal film 100 can be an alloy of nickel and any one of titanium (Ti), cobalt (Co), platinum (Pt), tungsten (W), erbium (Er), Yttrium (Y), niobium (Nb), and palladium (Pd). However, when metal other than nickel is used, it is necessary to change a ratio of a film thickness of the gate electrodes 40 and 42 to a film thickness of the metal film 100, and the temperature and time of the first and the second heat treating appropriately.

The gate insulation film 30 can be a high dielectric other than the above material, an oxide film, or an oxynitrided film of this high dielectric.

In the flattening process of the interlayer insulation film 80, the etching by the CMP can be stopped in a state that a silicon oxide film slightly remains on the upper surfaces of the first gate electrode 40 and the second gate electrode 42, respectively, and the rest of the silicon oxide film can be removed by etching like the RIE.

While the semiconductor device according to the above embodiment is applied to a flat transistor, the semiconductor device can be also applied to a transistor having a three-dimensional structure of a channel and a gate electrode like the Fin transistor.

The transistor according to the above embodiment can be manufactured on a silicon-on insulator (SOI) substrate.

1. A method of manufacturing a semiconductor device comprising:
forming a gate insulation film on a semiconductor substrate;
forming a gate electrode on the gate insulation film;
depositing a metal film on the gate electrode;
siliciding an upper part of the gate electrode by carrying out a first heat treating;
removing the metal film not silicided in the first heat treating; and
siliciding the gate electrode to a lower part of the gate electrode by carrying out a second heat treating.

2. The method of manufacturing a semiconductor device according to claim 1, wherein
after forming the gate electrode, depositing an insulating material to cover the gate electrode;
planarizing the insulating material to expose the upper surface of the gate electrode.

3. The method of manufacturing a semiconductor device according to claim 1, wherein
the gate electrode is made of polycrystalline silicon,
the metal film is made of any one of nickel (Ni), titanium (Ti), cobalt (Co), platinum (Pt), tungsten (W), erbium (Er), Yttrium (Y), niobium (Nb), or palladium (Pd).

4. The method of manufacturing a semiconductor device according to claim 1, wherein
the gate electrode is made of polycrystalline silicon,
the metal film is made of an alloy of nickel and any one of titanium (Ti), cobalt (Co), platinum (Pt), tungsten (W), erbium (Er), Yttrium (Y), niobium (Nb), and palladium (Pd).

5. The method of manufacturing a semiconductor device according to claim 1, wherein
the first heat treating is carried out at a temperature within a range from 250° C. to 400° C. for 20 or more seconds.

6. The method of manufacturing a semiconductor device according to claim 1, wherein
the first heat treating is carried out at a temperature within a range from 300° C. to 400° C. for 20 or more seconds.

7. The method of manufacturing a semiconductor device according to claim 1, wherein
the first heat treating is carried out at a temperature within a range from 325° C. to 375° C. for 20 or more seconds.

8. The method of manufacturing a semiconductor device according to claim 1, wherein
the second heat treating is carried out at a temperature within a range from 450° C. to 550° C. for 60 or more seconds.

9. The method of manufacturing a semiconductor device according to claim 1, wherein
the thickness of the metal film is equal to or smaller than 70% of the thickness of the gate electrode.

10. A method of manufacturing a semiconductor device comprising:
forming a gate insulation film on a semiconductor substrate;
depositing a gate electrode material on the gate insulation film;
depositing a cap material on the gate electrode material to cover the gate electrode material;
patterning the gate electrode material and the cap material in a gate electrode pattern to form a gate electrode and a cap;
forming spacers on said side surfaces of the gate electrode and on said side surfaces of the cap;
forming a source-drain layer on the semiconductor substrate using the gate electrode as a mask;
depositing a first metal film on the source-drain layer;
siliciding a surface of the source-drain layer with the first metal film;
depositing an insulating material to cover the source-drain layer;
planarizing the insulating material to expose the upper surface of the insulating material;
removing the cap;
depositing a second metal film on an upper surface of the gate electrode;
siliciding an upper part of the gate electrode by carrying out a first heat treating;
removing the second metal film not silicided in the first heat treating; and
siliciding the gate electrode to a lower part of the gate electrode by carrying out a second heat treating.

11. The method of manufacturing a semiconductor device according to claim 10, wherein
the gate electrode is made of polycrystalline silicon,
the first and the second metal films are made of any one of nickel (Ni), titanium (Ti), cobalt (Co), platinum (Pt), tungsten (W), erbium (Er), Yttrium (Y), niobium (Nb), or palladium (Pd).

12. The method of manufacturing a semiconductor device according to claim 10, wherein
the gate electrode is made of polycrystalline silicon,
the first and the second metal films are made of an alloy of nickel and any one of titanium (Ti), cobalt (Co), platinum (Pt), tungsten (W), erbium (Er), Yttrium (Y), niobium (Nb), and palladium (Pd).

13. The method of manufacturing a semiconductor device according to claim 10, wherein
the first heat treating is carried out at a temperature within a range from 250° C. to 400° C. for 20 or more seconds.

14. The method of manufacturing a semiconductor device according to claim 10, wherein
the first heat treating is carried out at a temperature within a range from 300° C. to 400° C. for 20 or more seconds.

15. The method of manufacturing a semiconductor device according to claim 10, wherein
the first heat treating is carried out at a temperature within a range from 325° C. to 375° C. for 20 or more seconds.

16. The method of manufacturing a semiconductor device according to claim 10, wherein
the second heat treating is carried out at a temperature within a range from 450° C. to 550° C. for 60 or more seconds.

17. The method of manufacturing a semiconductor device according to claim 10, wherein
the thickness of the second metal film is equal to or smaller than 70% of the thickness of the gate electrode.
